(19) United States
(12) Patent Application Publication
(10) Pub. No.: US 2020/0287465 A1
(43) Pub. Date: Sep. 10, 2020

(54) SWITCHED-MODE POWER SUPPLY WITH FIXED ON-TIME CONTROL SCHEME

(71) Applicant: QUALCOMM Incorporated, San Diego, CA (US)

(72) Inventors: Yikai WANG, San Diego, CA (US); Joseph Dale RUTKOWSKI, Chandler, AZ (US)

(21) Appl. No.: 16/295,449

(22) Filed: Mar. 7, 2019

(51) Int. Cl. H02M 3/335; H02M 1/14; H03K 4/62

(52) U.S. Cl. CPC H02M 3/33546; H03K 4/62; H02M 1/14

(57) ABSTRACT

Certain aspects of the present disclosure generally relate to a switch mode power supply (SMPS). The SMPS generally includes at least one switch, an inductive element coupled to the at least one switch, and control circuitry, the control circuitry being configured to control the at least one switch, during each switching cycle of a plurality switching cycles of the SMPS, to transfer charge from an input voltage (Vin) node of the SMPS to the inductive element during an on-time of the switching cycle and transfer the charge to an output voltage (Vout) node of the SMPS during an off-time of the switching cycle. The on-time may be set based on a duty ratio of the SMPS, the duty ratio representing a ratio between a voltage at the Vin node and a voltage at the Vout node, the on-time being fixed depending on the duty ratio of the SMPS.

### TECHNICAL FIELD

Certain aspects of the present disclosure generally relate to electronic circuits and, more particularly, to circuits for power regulation.

### BACKGROUND

A voltage regulator ideally provides a constant direct current (DC) output voltage regardless of changes in load current or input voltage. Voltage regulators may be classified as either linear regulators or switching regulators. While linear regulators tend to be small and compact, many applications may benefit from the increased efficiency of a switching regulator. A switching regulator may be implemented by a switched-mode power supply (SMPS), such as a buck converter or a boost converter.

Power management integrated circuits (power management ICs or PMIC) are used for managing the power requirement of a host system. A PMIC may be used in battery-operated devices, such as mobile phones, tablets, laptops, wearables, etc., to control the flow and direction of electrical power in the devices. The PMIC may perform a variety of functions for the device such as direct-current (DC)-to-DC conversion, battery charging, power-source selection, voltage scaling, power sequencing, etc.

### SUMMARY

Certain aspects of the present disclosure generally relate to a switched-mode power supply (SMPS). The SMPS generally includes at least one switch, an inductive element coupled to the at least one switch, and control circuitry. The control circuitry may be configured to control the at least one switch, during each switching cycle of a plurality switching cycles of the SMPS, to transfer charge from an input voltage (Vin) node of the SMPS to the inductive element during an on-time of the switching cycle and transfer the charge to an output voltage (Vout) node of the SMPS during an off-time of the switching cycle. In certain aspects, the control circuitry may also set the on-time of the SMPS based on a duty ratio of the SMPS, the duty ratio representing a ratio between a voltage at the Vin node and a voltage at the Vout node, wherein the on-time of the switching cycle is fixed depending on the duty ratio of the SMPS.

Certain aspects of the present disclosure generally relate to a method for voltage regulation. The method generally includes determining an on-time of a switching cycle of a switched-mode power supply (SMPS) based on a duty ratio of the SMPS, the duty ratio representing a ratio between a voltage at an input voltage (Vin) node of the SMPS and a voltage at an output voltage (Vout) node of the SMPS, wherein the on-time of the switching cycle is fixed depending on the duty ratio of the SMPS; transferring charge from the Vin node of the SMPS to an inductive element of the SMPS during the on-time; and transferring the charge to the Vout node of the SMPS during an off-time of the switching cycle.

Certain aspects of the present disclosure generally relate to an apparatus for voltage regulation. The apparatus generally includes means for determining an on-time of a switching cycle based on a duty ratio, the duty ratio representing a ratio between a voltage at an input voltage (Vin) node and a voltage at an output voltage (Vout) node, wherein the on-time of the switching cycle is fixed depending on the duty ratio of the SMPS; means for transferring charge from the Vin node to an inductive element during the on-time; and means for transferring the charge to the Vout node during an off-time of the switching cycle.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 illustrates a block diagram of an example device including a power regulator, according to certain aspects of the present disclosure.

FIG. 2 illustrates an example switched-mode power supply (SMPS) configured as a boost converter.

FIGS. 3A and 3B illustrate various signals of an SMPS, in accordance with certain aspects of the present disclosure.

FIG. 4 illustrates a duty ratio and inductor current with variable on-time across multiple switching cycles of an SMPS, in accordance with certain aspects of the present disclosure.

FIG. 5 illustrates a circuit 500 for generating a dynamic fixed on-time (FOT) using a digital implementation, in accordance with certain aspects of the present disclosure.

FIG. 6 illustrates a circuit for generating a dynamic FOT using an analog implementation, in accordance with certain aspects of the present disclosure.

FIG. 7 illustrates signals during different modes of operation of an SMPS, in accordance with certain aspects of the present disclosure.

FIGS. 8A-8D illustrate transitions between different operating modes of an SMPS, in accordance with certain aspects of the present disclosure.

FIGS. 9A and 9B illustrate SMPS behavior as a result of different operating mode transition threshold levels, in accordance with certain aspects of the present disclosure.

FIGS. 10A, 10B, and 10C are circuits for generating operating mode transition thresholds, in accordance with certain aspects of the present disclosure.

FIG. 11 is a graph illustrating a sampling point for setting an operating mode threshold, in accordance with certain aspects of the present disclosure.

FIG. 12 is a flow diagram illustrating example operations for voltage regulation, in accordance with certain aspects of the present disclosure.

### DETAILED DESCRIPTION

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

### An Example Device

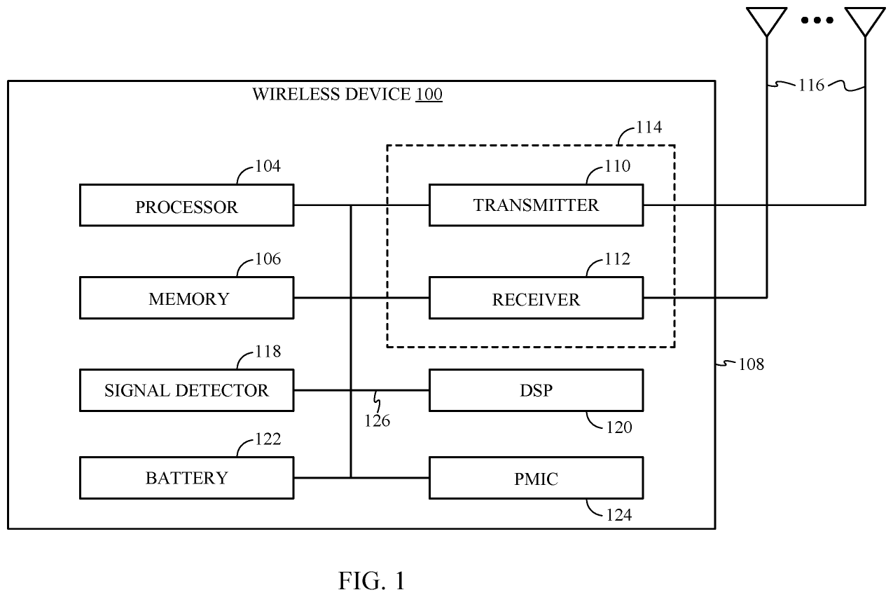

FIG. 1 illustrates a device 100. The device 100 may be a battery-operated device such as a cellular phone, a personal digital assistant (PDA), a handheld device, a wireless modem, a laptop computer, a tablet, a personal computer, etc. The device 100 is an example of a device that may be configured to implement the various systems and methods described herein.

The device 100 may include a processor 104 that controls operation of the device 100. The processor 104 may also be referred to as a central processing unit (CPU). Memory 106, which may include both read-only memory (ROM) and random access memory (RAM), provides instructions and data to the processor 104. A portion of the memory 106 may also include non-volatile random access memory (NVRAM). The processor 104 typically performs logical and arithmetic operations based on program instructions stored within the memory 106. The instructions in the memory 106 may be executable to implement the methods described herein.

The device 100 may also include a housing 108 that may include a transmitter 110 and a receiver 112 to allow transmission and reception of data between the device 100 and a remote location. The transmitter 110 and receiver 112 may be combined into a transceiver 114. A plurality of transmit antennas 116 may be attached to the housing 108 and electrically coupled to the transceiver 114. The device 100 may also include (not shown) multiple transmitters, multiple receivers, and multiple transceivers.

The device 100 may also include a signal detector 118 that may be used in an effort to detect and quantify the level of signals received by the transceiver 114. The signal detector 118 may detect such signals as total energy, energy per subcarrier per symbol, power spectral density and other signals. The device 100 may also include a digital signal processor (DSP) 120 for use in processing signals.

The device 100 may further include a battery 122 used to power the various components of the device 100. The device 100 may also include a power management integrated circuit (power management IC or PMIC) 124 for managing the power from the battery to the various components of the device 100. The PMIC 124 may perform a variety of functions for the device such as DC-to-DC conversion, battery charging, power-source selection, voltage scaling, power sequencing, etc. In certain aspects, the PMIC 124 includes a voltage regulator which may be implemented using a fixed on-time (FOT) mode of operation, as described herein.

The various components of the device 100 may be coupled together by a bus system 126, which may include a power bus, a control signal bus, and a status signal bus in addition to a data bus.

### Example Switched-Mode Power Supply

A direct-current (DC)-to-DC converter is an apparatus that converts an input DC voltage into a constant regulated output DC voltage for application to a load. In some cases, a switching voltage regulator may employ a switch, such as a power field-effect transistor (FET), coupled either in series or in parallel with a load. The voltage applied to the load is regulated by controlling the on-time and off-time of the switch using control circuitry which varies the duty cycle applied to the switch based on the ratio between the input DC voltage and the output DC voltage.

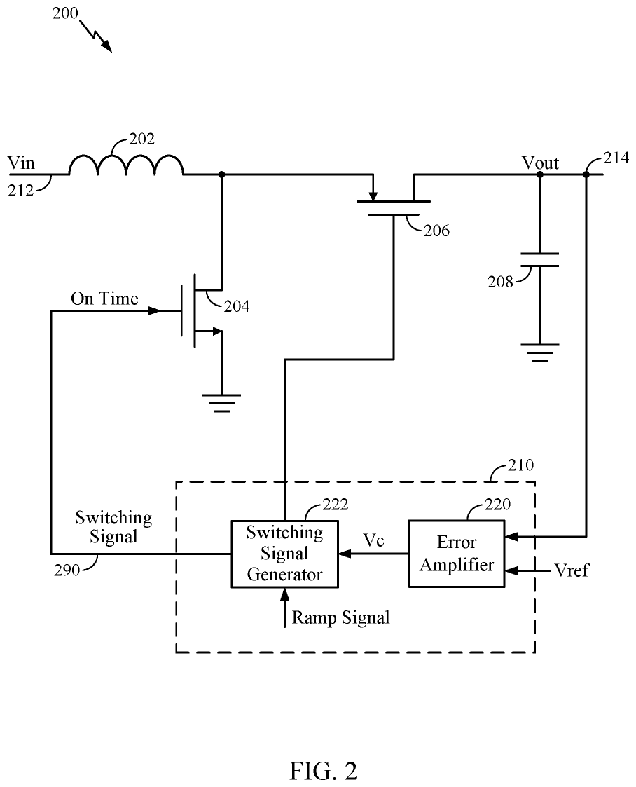

FIG. 2 illustrates an example SMPS 200 configured as a boost converter. As illustrated, the SMPS 200 includes an inductive element 202 coupled to switches 204, 206. During on-time of the switch 204 (e.g., when switch 204 is closed and switch 206 is open), current flows from node 212 (input voltage (Vin) node) to the reference potential node (e.g., electric ground), charging the inductive element 202. During off-time of the switch 204 (e.g., when switch 204 is open and switch 206 is closed), the stored charge on the inductive element 202 is transferred to the capacitive element 208 coupled to the output voltage (Vout) node 214. In certain aspects, control circuitry 210 (also referred to as “feedback circuitry”) may include an error amplifier 220, which may be implemented with a loop filter. The error amplifier 220 may be used to compare the output voltage Vout with a reference voltage Vref to generate a loop filter voltage Vc, as illustrated. The loop filter voltage Vc is provided to a switching signal generator 222 for generating a switching signal 290 (e.g., a pulse-width modulation (PWM) signal) based on a ramp signal, as illustrated. Any of various suitable control techniques may be used to control the switch 204, including PWM and/or pulse skipping mode (PSM), as described in more detail herein. The ramp signal may be generated based on a current sense signal representing the current across the inductive element 202, further adjusted for slope compensation. Slope compensation is a technique used to generate the switching signal 290 to overcome stability issues that may otherwise be present with current-mode switching power supplies. The switching signal generator 222 may control a duty cycle of switching signals used to drive the switches 204, 206 to regulate the output voltage Vout.

The duty cycle of the switching signal may be varied using a fixed frequency approach in which the switching frequency of the switching signal is fixed. The output voltage may be increased by increasing the on-time of the switch 204 and decreased by decreasing the on-time of the switch 204. The control circuitry 210 may be used to vary the on-time of the switch 204 so that a regulated output voltage is maintained in accordance with the reference voltage Vref. While FIG. 2 illustrates a boost-type SMPS to facilitate understanding, the aspects described herein may be implemented for any type of SMPS, such as a buck converter or a buck-boost converter.

Certain aspects of the present disclosure are generally directed to an SMPS implemented using a PSM of operation. PSM allows the control circuitry 210 to skip one or more switching cycles (or pulses) of the switching signal to improve efficiency for light load conditions. Certain aspects of the present disclosure also provide techniques for reducing a ripple voltage at the output of the SMPS to avoid noise coupling for sensitive components, such as active-matrix organic light-emitting diode (AMOLED) panels.

With conventional PSM operation, the on-time (e.g., inductor charging time) may be determined by the loop filter voltage Vc. The loop bandwidth of an SMPS may be low (e.g., one tenth to one third of the switching frequency), and as a result, an increase in the output voltage may be difficult to detect in a single switching period. Thus, a succession of pulses may build up a high amount of inductor current. At light load currents, too much power may be delivered to the output of the SMPS, causing large ripple voltage. Certain aspects of the present disclosure are directed to reducing high inductor current by limiting the peak inductor current of each cycle. For example, a fixed on time (FOT) for each cycle may be implemented such that the peak inductor current is limited in order to deliver low enough power in one switching cycle that avoids (or at least reduces) fast transients at the loop filter voltage.

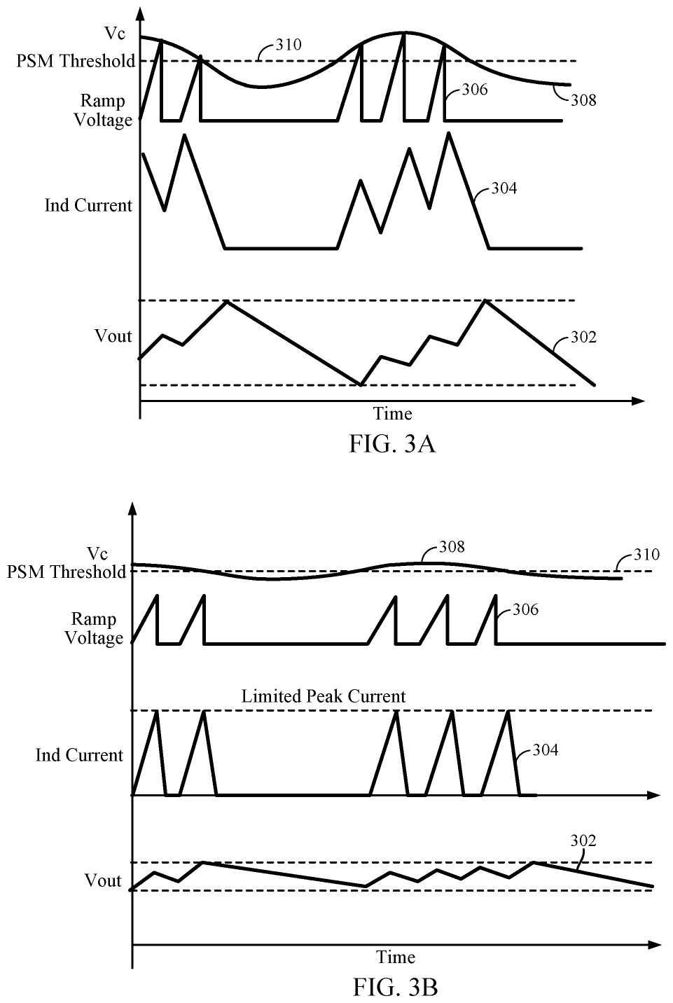

FIGS. 3A and 3B illustrate output voltage Vout 302, inductor current 304, ramp signal 306, and loop filter voltage Vc 308, in accordance with certain aspects of the present disclosure. As illustrated, when the loop filter voltage Vc 308 is less than a pulse skipping mode (PSM) threshold 310, one or more switching cycles of the SMPS (e.g., the ramp signal) may be skipped. In PSM operation with variable on-time based on the loop filter voltage Vc, as illustrated in FIG. 3A, the ramp signal is implemented based on inductor current sensing and slope compensation, resulting in the peak of the ramp signal being varied based on the loop filter voltage Vc 308, causing high inductor current and large ripple in the output voltage Vout 302. Certain aspects of the present disclosure are directed to setting a limited peak voltage for the ramp signal, as illustrated in FIG. 3B, by implementing a fixed on-time for the SMPS. By setting a limited peak voltage for the ramp signal, the peak inductor current is also limited, reducing inductor ripple current as compared to implementations with variable on-time. Reducing the inductor ripple current also reduces the ripple voltage (e.g., ripple of Vout) at the output of the SMPS.

In order to limit the power delivered to a load in a single switching cycle, a short on-time for the SMPS may be implemented. A short on-time may be realized using high speed and accurate current sensing, which may be expensive to implement. Certain aspects of the present disclosure implement a fixed on-time to limit the peak inductor current without directly sensing the inductor current. The fixed on-time may be adjusted based on a duty cycle of the SMPS, the duty cycle representing the ratio between the input and output voltages of the SMPS. For a boost converter the duty cycle (D) may be expressed as D=1−(Vi/Vo), where Vi is the input voltage and Vo is the output voltage of the boost converter.

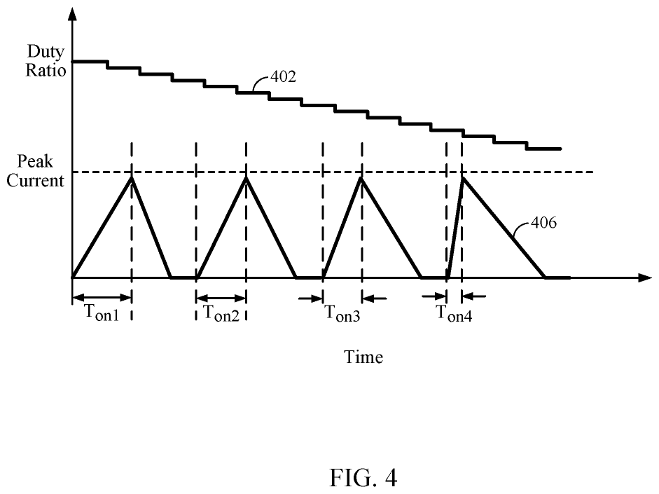

FIG. 4 illustrates a duty ratio 402 and inductor current 406 with fixed on-time (FOT) that changes across multiple switching cycles of the SMPS (referred to herein as “dynamic FOT”), in accordance with certain aspects of the present disclosure. As illustrated, as the duty ratio 402 of the SMPS decreases, the on-time (Tₒₙ₁ to Tₒₙ₄) decreases while maintaining a constant peak inductor current. In other words, for low input voltage, but high output voltage, a longer on-time may be utilized to deliver more power in a single switching cycle and reduce the switching loss. For high input voltage but low output voltage, a shorter on-time may be employed to avoid high voltage ripple. In other words, the FOT is set dynamically depending on a given duty ratio 402 (e.g., instead of the loop filter voltage Vc) to implement a pulse skipping mode (PSM) of operation with FOT.

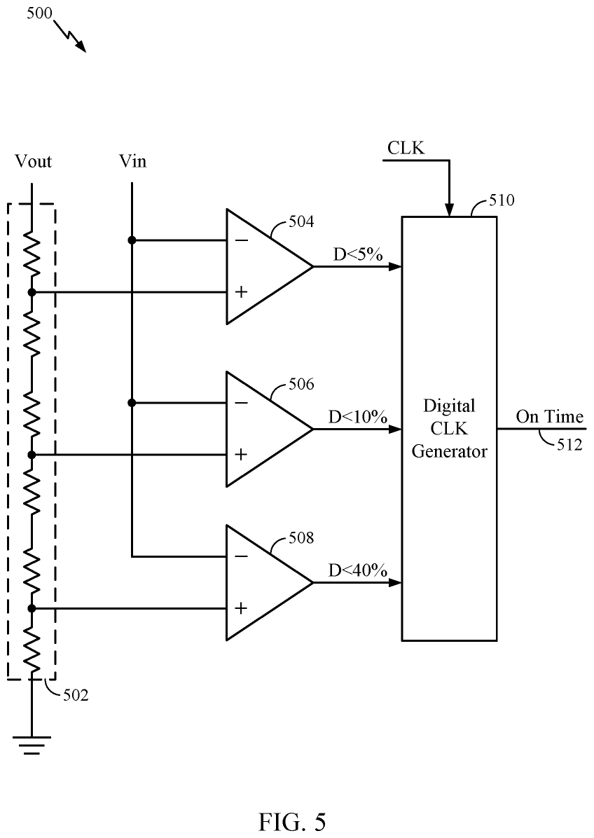

FIG. 5 illustrates a circuit 500 for generating a dynamic FOT switching signal using a digital implementation, in accordance with certain aspects of the present disclosure. As illustrated, the circuit 500 includes a voltage divider network 502 having tap nodes coupled to positive input terminals of the comparators 504, 506, 508. The voltage divider network 502 generates a voltage-divided signal at each of the tap nodes. For example, the voltage at the positive input terminal of the comparator 504 may be equal to 95% of the output voltage Vout, the voltage at the positive input terminal of the amplifier 506 may be equal to 90% of the output voltage Vout, and the voltage at the positive input terminal of the amplifier 508 may be equal to 60% of the output voltage Vout. Each of the voltage-divided signals is compared with an input voltage (e.g., Vin) coupled to the negative input terminals via the comparators 504, 506, 508. Thus, the outputs of the comparators 504, 506, 508 indicate whether the duty ratio (e.g., ratio of Vout and Vin) is less than 5%, less than 10%, or less than 40%, respectively. Based on the outputs of the comparators 504, 506, 508, the digital clock generator circuit 510 generates a switching signal 290 for the SMPS and adjusts the on-time of the switching signal 290 at the output node 512. The digital clock generator circuit 510 may be operated according to an input clock (CLK) signal (e.g., a 19.2 MHz clock). While the circuit 500 indicates whether the duty cycle is less than three duty cycle thresholds (e.g., 5%, 10%, and 40%), the circuit 500 may be implemented to indicate whether the duty cycle is less than any number of duty cycle thresholds. Furthermore, the voltage divider network 502 may output any of various suitable voltage-divided signals having different potentials than those provided in the example above.

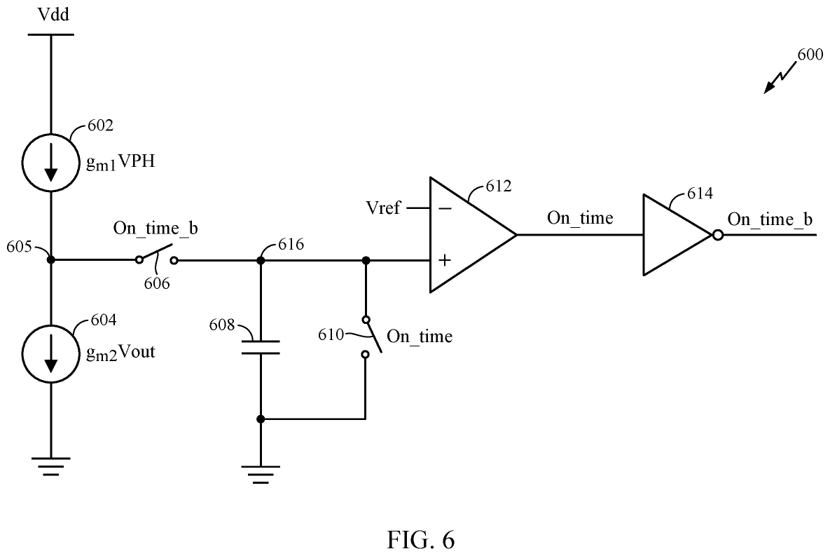

FIG. 6 illustrates a circuit 600 for generating a dynamic FOT control signal using an analog implementation, in accordance with certain aspects of the present disclosure. The circuit 600 includes current sources 602, 604 coupled to a voltage rail Vdd and a reference potential node (e.g., electric ground), respectively. The current source 602 sources a current representative of the input voltage Vin (e.g., product of a transconductance gm1 and Vin) to a common node 605, and the current source 604 sinks a current representative of the output voltage Vout (e.g., product of a transconductance gm2 and Vout) from the common node 605.

The current sources 602, 604 are selectively coupled to a shunt capacitive element 608 through a switch 606. When the switch 606 is closed, the shunt capacitive element 608 is charged at a rate dependent on the ratio of Vin and Vout (duty ratio). The capacitive element 608 is coupled in parallel with another switch 610. When switch 610 is closed, the capacitive element 608 is discharged. The switches 606, 610 are controlled via inverse signals on_time_b and on_time, respectively, as illustrated. The amplifier 612 compares the voltage at comparison node 616 (e.g., voltage across capacitive element 608) with a reference voltage Vref, and adjusts the on-time of the SMPS, as well as the on-time control signal of switch 610, accordingly. Therefore, as the duty ratio increases, the amount of charge transferred to the capacitive element 608 increases, resulting in an increase in the on-time of the switching signal at the output of the amplifier 612. The inverter 614 is implemented at the output of the amplifier 612 to generate the inverse of the on time control signal (e.g., on_time_b control signal) for controlling switch 606, as illustrated.

Although the average load current of an SMPS may be low (e.g., 20 mA), an SMPS may have to support higher load currents (e.g., 200 mA). Therefore, a PWM mode of operation must be enabled in some scenarios to increase the load current capability of the SMPS, in accordance with certain aspects of the present disclosure.

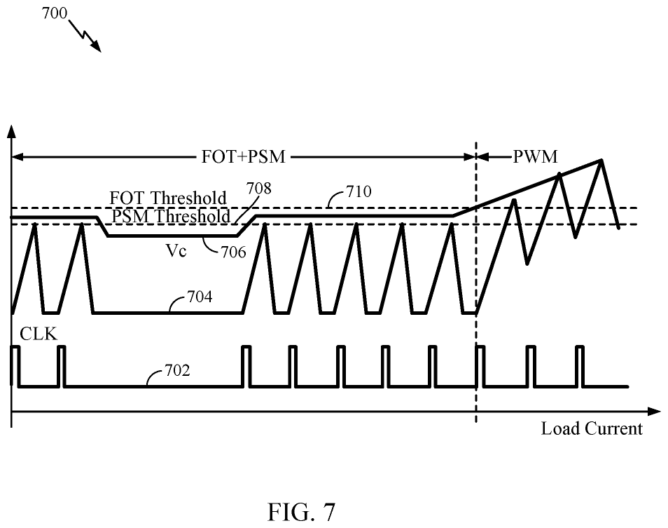

FIG. 7 is a graph 700 illustrating SMPS signals during FOT, PSM, and PWM modes of operation, in accordance with certain aspects of the present disclosure. As illustrated, a PSM threshold 708 may be implemented to trigger a transition between FOT and PSM modes of operation, and a FOT threshold 710 may be implemented to trigger a transition between FOT and PWM modes of operation. For example, when the loop filter voltage Vc 706 is lower than the PSM threshold 708, the SMPS stops switching (e.g., clock signal 702 used by the switching signal generator 222 to generate pulses of a switching signal stops switching) until the loop filter voltage Vc is greater than the PSM threshold 708, as illustrated. This is the PSM mode of operation, in which there is no inductor current 704. When the loop filter voltage Vc 706 is between the PSM threshold 708 and the FOT threshold 710, the SMPS enters the FOT mode of operation, during which the on-times of the switching cycles are fixed, based on a duty ratio of the SMPS, as described herein. In the FOT mode, the inductor current 704 has a limited peak current, as illustrated in FIG. 7. When the loop filter voltage Vc 706 is greater than the FOT threshold 710, a PWM mode of operation is enabled during which the on-times of the switching cycles are no longer fixed based on a duty ratio of the SMPS, as described herein. Thus, as illustrated, during the PWM mode of operation, the inductor current 704 increases.

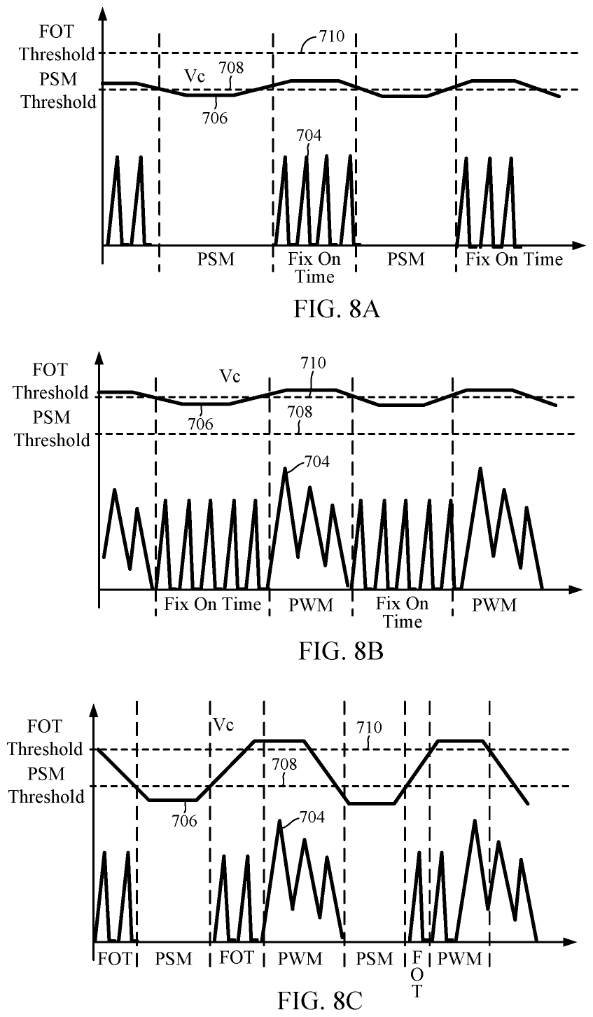

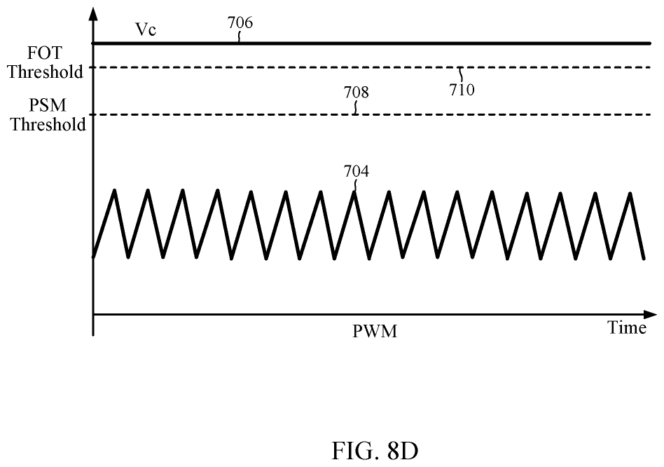

FIGS. 8A-8D illustrate transitions between different operating modes of an SMPS, in accordance with certain aspects of the present disclosure. In certain aspects, the SMPS may be in a PSM mode of operation when the loop filter voltage Vc is below the PSM threshold 708, and transition to a FOT mode of operation when the loop filter voltage Vc rises above the PSM threshold 708. For example, as illustrated in FIG. 8A, the SMPS may transition between a PSM mode of operation, during which pulses of the SMPS are skipped, and a FOT mode of operation, during which pulses of the SMPS are resumed, but with a fixed on-time.

In some cases, the SMPS may be in a FOT mode of operation when the loop filter voltage Vc is above PSM threshold 708 but below the FOT threshold 710, and transition to the PWM mode of operation when the loop filter voltage Vc rises above the FOT threshold 710. For example, as illustrated FIG. 8B, the SMPS may transition between a FOT mode of operation, during which pulses of the SMPS have a fixed on-time, and a PWM mode of operation, during which pulses of the SMPS are not fixed, as described herein.

In some cases, the loop filter voltage may vary from a voltage below the PSM threshold 708 to above the FOT threshold 710, and as a result, the SMPS may transition between PSM, FOT, and PWM modes of operations. For example, as illustrated FIG. 8C, the SMPS may transition between a PSM mode of operation during which pulses of the SMPS are skipped, a FOT mode of operation, during which pulses of the SMPS have a fixed on-time, and a PWM mode of operation, during which pulses of the SMPS are not fixed, as described herein. As illustrated, in FIG. 8D, the loop filter voltage Vc may remain above the FOT threshold 710, resulting in the SMPS only operating in the PWM mode of operation.

The levels of the PSM and FOT thresholds 708, 710 are important. If the PSM and FOT thresholds are too low, the SMPS may operate in a PWM mode of operation during light load conditions. On the other hand, if the PSM and FOT thresholds are too high, the initial pulse after transition to the PWM mode of operation may result in high inductor current causing large voltage disturbances.

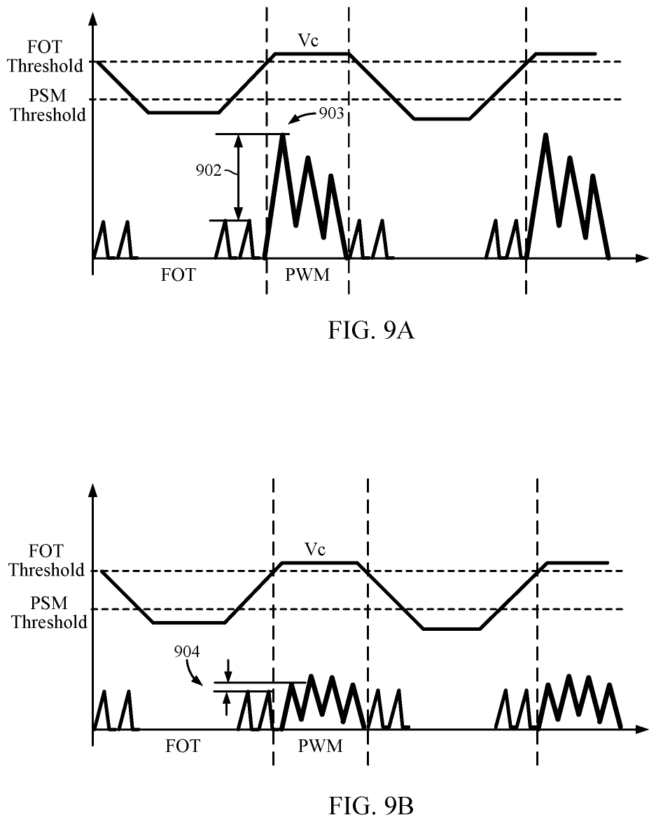

FIGS. 9A and 9B illustrate SMPS behavior as a result of different PSM and FOT threshold levels, in accordance with certain aspects of the present disclosure. As illustrated in FIG. 9A, the levels of the PSM and FOT thresholds may be too high resulting in high inductor current during the initial pulse 903 after the transition to the PWM mode of operation. For example, as illustrated by arrow 902, a large peak current difference may be observed from the last pulse during the FOT mode of operation to the initial pulse 903 after the transition to the PWM mode of operation. Therefore, the PSM and FOT thresholds should be set such that the peak inductor current during the FOT mode of operation is slightly below the peak inductor current during the initial pulse after the transition to the PWM mode of operation, as illustrated by the arrows 904 in FIG. 9B.

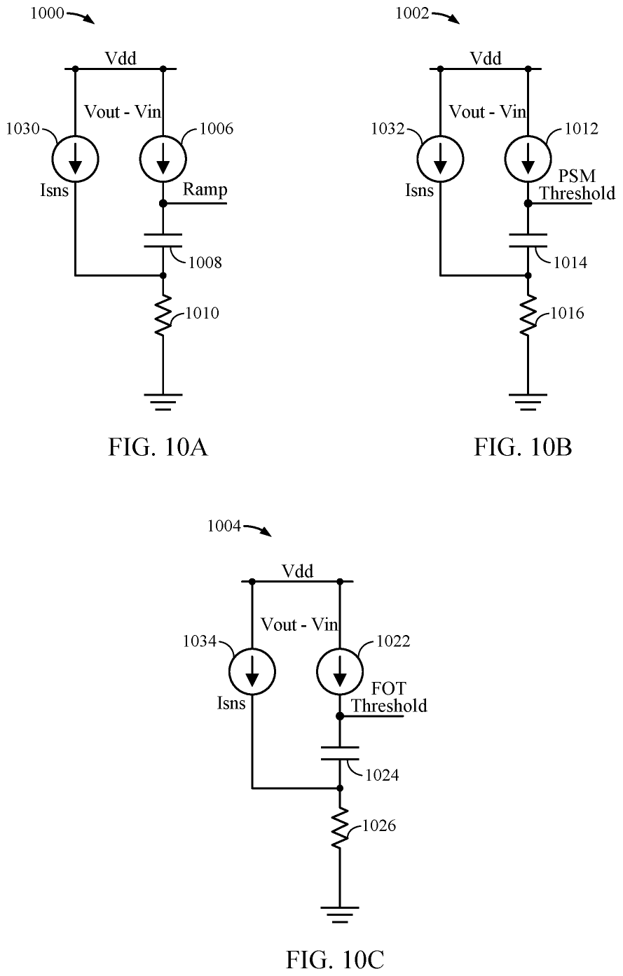

FIGS. 10A, 10B, and 10C are circuits 1000, 1002, 1004 for generating a ramp signal, a PSM threshold, and a FOT threshold, respectively, in accordance with certain aspects of the present disclosure. The value of loop filter voltage Vc in PWM mode of operation may be determined based on the ramp signal, which represents a sensed inductor current signal Isns (e.g., representing current across inductive element 202) adjusted for slope compensation. In certain aspects, the PSM and FOT thresholds may include the same slope compensation as the ramp signal, and therefore, may be used to set limits regarding the peak inductor current. For example, with regards to circuit 1000, the ramp signal may be generated via the circuit 1000 having a current source 1030 sourcing a current representing the inductor current Isns, a current source 1006 coupled to the capacitive element 1008, and a resistive element 1010. The current source 1006 may generate a current representing the duty ratio of the SMPS. Therefore, the loop filter voltage Vc may be represented by the following equation:

$${V}_{c} = {I}_{L - peak} \times R + {\int }_{0}^{Ton} \frac{( Vout - Vin ) {g}_{m}}{C}$$

where I_{L-peak} represents the peak inductor current of the SMPS, R represents the resistance of resistive element 1010, Tₒₙ is the on-time of the SMPS, gₘ is the transconductance of the current source 1006, and C is the capacitance of the capacitive element 1008. The slope compensation may be represented by the equation:

$${T}_{on} \frac{( Vout - Vin ) {g}_{m}}{C}$$

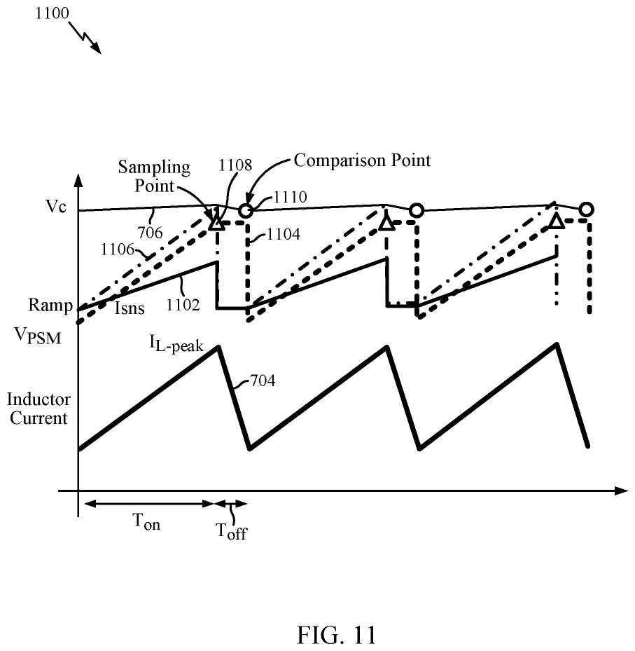

The current flow across the resistive element 1010 may represent the inductor current Isns, as illustrated. In a similar fashion, the PSM threshold may be generated using the circuit 1002 having a current source 1012 coupled to capacitive element 1014 and the resistive element 1016. The voltage at node 1018 (e.g., PSM voltage (V_{PSM})) may be represented by the following equation:

$${V}_{PSM} = {I}_{ref} \times R + {\int }_{0}^{Ton} \frac{( Vout - Vin ) {g}_{m}}{C}$$

where I_{ref} is the current sourced by current source 1032, R is the resistance of the resistive element 1016, gₘ is the transconductance of the current source 1012, and C is the capacitance of the capacitive element 1014. The circuit 1004 operates in a similar fashion for generating the FOT threshold. For example, voltage at node 1020 (e.g., FOT voltage (V_{FOT})) may be represented by the equation:

$${V}_{FOT} = {I}_{ref 1} \times R + {\int }_{0}^{Ton} \frac{( Vout - Vin ) {g}_{m}}{C}$$

where I_{ref2} is the current sourced by current source 1034, Tₒₙ is the ON time of the SMPS, R is the resistance of the resistive element 1026, gₘ is the transconductance of the current source 1022, and C is the capacitance of the capacitive element 1024. The circuits 1002, 1004 allow the PSM and FOT thresholds to be generated in a manner such that the thresholds only depend on the peak inductor current value, as described with respect to FIG. 11.

FIG. 11 is a graph 1100 illustrating a sampling point for setting a PSM threshold, in accordance with certain aspects of the present disclosure. The graph 1100 illustrates an inductor current sense signal Isns 1102, the ramp signal 1106, and V_{PSM} 1104 (e.g., voltage at node 1018). As illustrated, V_{PSM} may be sampled at the sampling point 1108 at the end of the on-time (Tₒₙ). The PSM voltage V_{PSM} may be held and compared with the loop filter voltage Vc at the comparison point 1110 at the end of the off-time (T_{off}). Based on the comparison, the SMPS may transition between the FOT and PSM modes of operation, as described herein.

The FOT voltage V_{FOT} may be sampled, held, and compared to the loop filter voltage Vc in a similar manner for determining when to transition between the FOT and PWM modes of operation as described herein. In this manner, the PSM and FOT voltages (V_{PSM}, V_{FOT}) implement thresholds for determining the operating mode transitions described herein, based on the inductor current (Isns) without slope compensation. In other words, by sampling and holding the PSM voltage (or FOT voltage) before comparison with the loop filter voltage Vc, the adjustment for slope compensation is effectively cancelled out of the PSM threshold (or FOT threshold) for comparison to the loop filter voltage Vc. In certain aspects, the PSM and FOT thresholds may be recalculated in every switching cycle of the SMPS.

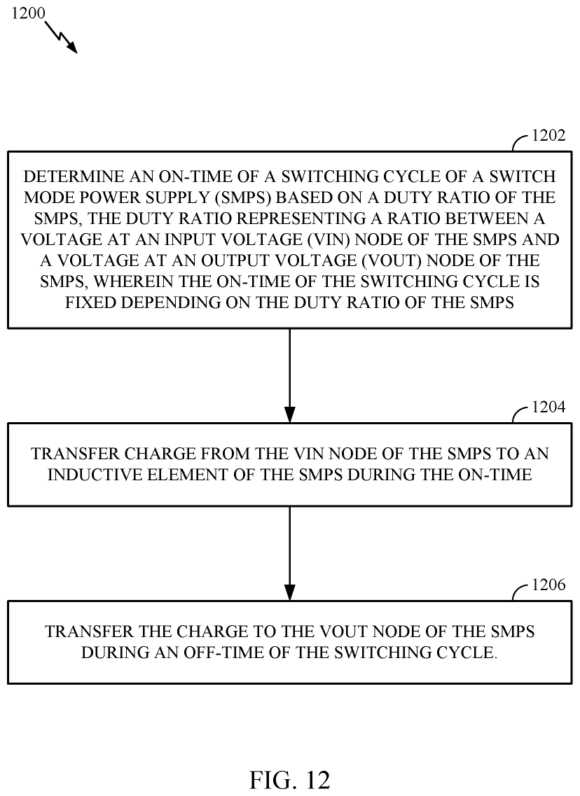

FIG. 12 is a flow diagram illustrating example operations 1200 for voltage regulation, in accordance with certain aspects of the present disclosure. The operations 1200 may be performed by an SMPS, such as the SMPS 200 of FIG. 2.

The operations 1200 may begin, at block 1202, with the SMPS determining an on-time of a switching cycle of an SMPS based on a duty ratio of the SMPS. The duty ratio may represent a ratio between a voltage at an input voltage (Vin) node of the SMPS and a voltage at an output voltage (Vout) node of the SMPS. For example, the on-time of the switching cycle may be fixed depending on the duty ratio of the SMPS. At block 1204, the SMPS may transfer charge from the Vin node of the SMPS to an inductive element of the SMPS during the on-time, and at block 1206, transfer the charge to the Vout node of the SMPS during an off-time of the switching cycle. In certain aspects, the operations 1200 may also include reducing the on-time in response to the duty ratio decreasing.

In certain aspects, determining the on-time of the switching cycle may include sourcing (e.g., via current source 602) a first current to a common node (e.g., common node 605) selectively coupled to a capacitive element (e.g., capacitive element 608), the first current representing the voltage at the Vin node, and sinking (e.g., via current source 604) a second current from the common node, the second current representing the voltage at the Vout node. The operations 1200 may also include selectively discharging (e.g., via switch 610) the capacitive element during the on-time, the capacitive element being coupled to a comparison node (e.g., comparison node 616), selectively coupling (e.g., via switch 606) the common node to the capacitive element during the off-time; and comparing (e.g., via amplifier 612) a signal at the comparison node with a reference voltage, the on-time being determined based on the comparison.

In certain aspects, the on-time determined based on the duty ratio may be used during a fixed-on time (FOT) mode of operation of the SMPS. In this case, the operations 1200 may include comparing (e.g., via the switching signal generator 222) a loop filter voltage of the SMPS with a voltage threshold, and transitioning (e.g., via the switching signal generator 222) the SMPS between the FOT mode of operation and a pulse skipping mode of operation based on the comparison. In some cases, the operations 1200 may include comparing (e.g., via the switching signal generator 222) a loop filter voltage of the SMPS with a voltage threshold, and transitioning (e.g., via the switching signal generator 222) the SMPS between the FOT mode of operation and a pulse width modulation (PWM) mode of operation based on the comparison control.

In certain aspects, the operations 1200 may include sourcing (e.g., via current source 1012 or 1022) a current representing the duty ratio of the SMPS to a series circuit having a capacitive element (e.g., capacitive element 1014 or 1024) and a resistive element (e.g., resistive element 1016 or 1026), sampling (e.g., via the switching signal generator 222) a voltage at a node between the current source and the series circuit, and transitioning (e.g., via the switching signal generator 222) between the FOT mode of operation and another mode of operation (e.g., the PSM or PWM modes of operation) based on the sampled voltage. In certain aspects, the voltage at the node may be sampled after the on-time of the switching cycle. In this case, the operations 1200 also include comparing the sampled voltage to a loop filter voltage of the SMPS after the off-time of the switching cycle, the transitioning between the FOT mode of operation and the other mode of operation being based on the comparison.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

In certain aspects, means for determining an on-time, means for reducing an on-time, means for comparing, and means for transitioning may be implemented by a switching signal generator, such as the switching signal generator 222 of FIG. 2. In certain aspects, means for transferring charge may be implemented by one or more switches, such as the switch 204 and switch 206. In certain aspects, means for sourcing may be implemented by a current source such as the current source 602. In certain aspects, means for sinking may be implemented by a current source, such as the current source 604. In certain aspects, means for selectively discharging may be implemented by a switch, such as the switch 610. In certain aspects, means for selectively coupling may be implemented by a switch, such as the switch 606. In certain aspects, means for comparing may be implemented by an amplifier, such as the amplifier 612.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-h, a-c, b-c, and a-b-c, as well as any combination with multiples of the same element (e.g., a-a, ca-a-a, a-a-b, a-a-c, a-b-b, a-c-c, b-b, b-b-b, b-b-c, c-c, and c-c-c or any other ordering of a, b, and c).

The various illustrative logical blocks, modules and circuits described in connection with the present disclosure may be implemented or performed with discrete hardware components designed to perform the functions described herein. The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes and variations may be made in the arrangement, operation and details of the methods and apparatus described above without departing from the scope of the claims.

1. A switched-mode power supply (SMPS), comprising:
at least one switch;
an inductive element coupled to the at least one switch; and
control circuitry configured to:
control the at least one switch, during each switching cycle of a plurality switching cycles of the SMPS, to transfer charge from an input voltage (Vin) node of the SMPS to the inductive element during an on-time of the switching cycle and transfer the charge to an output voltage (Vout) node of the SMPS during an off-time of the switching cycle; and
set the on-time of the switching cycle based on a duty ratio of the SMPS, the duty ratio representing a ratio between a voltage at the Vin node and a voltage at the Vout node, wherein the on-time of the switching cycle is fixed depending on the duty ratio of the SMPS, wherein the control circuitry is configured to set the on-time of the switching cycle such that the on-time remains fixed while the duty ratio of the SMPS remains constant.

2. The SMPS of claim 1, wherein the control circuitry is configured to reduce the on-time in response to the duty ratio decreasing.

3. The SMPS of claim 1, wherein the control circuitry comprises:
a voltage divider network having tap nodes, each of the tap nodes being coupled to a positive input terminal of an amplifier, negative input terminals of the amplifiers being coupled to the Vin node; and
a digital clock generation circuit having inputs coupled to outputs of the amplifiers, wherein the on-time of the switching cycle is set based on a voltage at an output of the digital clock generation circuit.

4. The SMPS of claim 1, wherein the control circuitry comprises:
a first switch;
a capacitive element selectively coupled to a common node of the control circuitry by the first switch;
a second switch coupled in parallel with the capacitive element;
a first current source configured to source a first current to the common node of the control circuitry, the first current representing the voltage at the Vin node;
a second current source configured to sink a second current from the common node of the control circuitry, the second current representing the voltage at the Vout node; and
an amplifier having a positive input terminal coupled to comparison node between the capacitive element and the first switch, a negative input terminal of the amplifier being coupled to a reference voltage (Vref) node; and
an inverter coupled to an output of the amplifier, wherein the first switch is configured to be controlled based on a signal at the output of the inverter, and the second switch is configured to be controlled based on another signal at the output of the amplifier.

5. The SMPS of claim 1, wherein:
the control circuitry is configured to set the on-time of the switching cycle based on the duty ratio during a fixed-on time (FOT) mode of operation of the SMPS;
the control circuitry comprises an error amplifier configured to compare the voltage at the Vout node with a reference voltage; and
the control circuitry is further configured to:
compare a voltage at an output of the error amplifier with a voltage threshold; and
transition the SMPS between the FOT mode of operation and a pulse skipping mode of operation of the SMPS based on the comparison.

6. The SMPS of claim 1, wherein:
the control circuitry is configured to set the on-time of the switching cycle based on the duty ratio during a fixed-on time (FOT) mode of operation of the SMPS;
the control circuitry comprises an error amplifier configured to compare the voltage at the Vout node with a reference voltage; and
the control circuitry is further configured to:
compare a voltage at an output of the error amplifier with a voltage threshold; and
transition the SMPS between the FOT mode of operation and a pulse width modulation (PWM) mode of operation based on the comparison.

7. The SMPS of claim 1, wherein:
the control circuitry is configured to set the on-time of the switching cycle based on the duty ratio during a fixed-on time (FOT) mode of operation of the SMPS;
the control circuitry comprises:
a current source configured to generate a current representing the duty ratio of the SMPS;
a series circuit coupled to the current source, the series circuit having a capacitive element coupled in series with a resistive element; and
the control circuitry is configured to:
sample a voltage at a node between the current source and the series circuit; and
transition between the FOT mode of operation and another mode of operation based on the sampled voltage.

8. The SMPS of claim 7, wherein:
the control circuitry comprises an error amplifier configured to compare the voltage at the Vout node with a reference voltage; and
the control circuitry is configured to:
sample the voltage at the node after the on-time of the switching cycle; and
compare the sampled voltage to a voltage at an output of the error amplifier after the off-time of the switching cycle, the control circuitry being configured to transition between the FOT mode of operation and the other mode of operation based on the comparison.

9. The SMPS of claim 1, wherein the SMPS is configured as a buck converter, a boost converter, or a buck-boost converter.

10. A method for voltage regulation, comprising:
determining an on-time of a switching cycle of a switched-mode power supply (SMPS) based on a duty ratio of the SMPS, the duty ratio representing a ratio between a voltage at an input voltage (Vin) node of the SMPS and a voltage at an output voltage (Vout) node of the SMPS, wherein the on-time of the switching cycle is fixed depending on the duty ratio of the SMPS, wherein the on-time is determined such that the on-time of the switching cycle remains fixed while the duty ratio of the SMPS remains constant;
transferring charge from the Vin node of the SMPS to an inductive element of the SMPS during the on-time; and
transferring the charge to the Vout node of the SMPS during an off-time of the switching cycle.

11. The method of claim 10, further comprising reducing the on-time in response to the duty ratio decreasing.

12. The method of claim 10, wherein determining the on-time of the switching cycle comprises:
sourcing a first current to a common node selectively coupled to a capacitive element, the first current representing the voltage at the Vin node;
sinking a second current from the common node, the second current representing the voltage at the Vout node;
selectively discharging the capacitive element during the on-time, the capacitive element being coupled to a comparison node;
selectively coupling the common node to the capacitive element during the off-time; and
comparing a signal at the comparison node with a reference voltage, the on-time being determined based on the comparison.

13. The method of claim 10, wherein:
the on-time determined based on the duty ratio is used during a fixed-on time (FOT) mode of operation of the SMPS; and
the method further comprises:
comparing a loop filter voltage of the SMPS with a voltage threshold; and
transitioning the SMPS between the FOT mode of operation and a pulse skipping mode of operation based on the comparison of the loop filter voltage of the SMPS with the voltage threshold.

14. The method of claim 10, wherein:
the on-time of the SMPS determined based on the duty ratio is used during a fixed-on time (FOT) mode of operation of the SMPS; and
the method further comprises:
comparing a loop filter voltage of the SMPS with a voltage threshold; and
transitioning the SMPS between the FOT mode of operation and a pulse width modulation (PWM) mode of operation based on the comparison.

15. The method of claim 10, wherein:
the on-time of the switching cycle determined based on the duty ratio is used during a fixed-on time (FOT) mode of operation of the SMPS;
the method further comprises:
sourcing a current representing the duty ratio of the SMPS to a series circuit having a capacitive element and a resistive element;
sampling a voltage at a node coupled to the series circuit; and
transitioning between the FOT mode of operation and another mode of operation based on the sampled voltage.

16. The method of claim 15, wherein:
the voltage at the node is sampled after the on-time of the switching cycle; and
the method further comprises comparing the sampled voltage to a loop filter voltage of the SMPS after the off-time of the switching cycle, the transitioning between the FOT mode of operation and the other mode of operation being based on the comparison.

17. An apparatus for voltage regulation, comprising:
means for determining an on-time of a switching cycle based on a duty ratio, the duty ratio representing a ratio between a voltage at an input voltage (Vin) node and a voltage at an output voltage (Vout) node, wherein the on-time of the switching cycle is fixed depending on the duty ratio of the SMPS, wherein the means for determining is configured to set the on-time of the switching cycle such that the on-time remains fixed while the duty ratio of the SMPS remains constant;
means for transferring charge from the Vin node to an inductive element during the on-time; and
means for transferring the charge to the Vout node during an off-time of the switching cycle.

18. The apparatus of claim 17, further comprising means for reducing the on-time in response to the duty ratio decreasing.

19. The apparatus of claim 17, wherein means for determining the on-time of the switching cycle comprises:
means for sourcing a first current to a common node selectively coupled to a capacitive element, the first current representing the voltage at the Vin node;
means for sinking a second current from the common node, the second current representing the voltage at the Vout node;
means for selectively discharging the capacitive element during the on-time, the capacitive element being coupled to a comparison node;
means for selectively coupling the common node to the capacitive element during the off-time; and
means for comparing a signal at the comparison node with a reference voltage, the on-time being determined based on the comparison.

20. The apparatus of claim 17, wherein:
the on-time determined based on the duty ratio is used during a fixed-on time (FOT) mode of operation of the apparatus; and
the apparatus further comprises:
means for comparing a loop filter voltage of the apparatus with a voltage threshold; and
means for transitioning between the FOT mode of operation and a pulse skipping mode of operation based on the comparison of the loop filter voltage of the apparatus with the voltage threshold.
